(19) United States
(12) Patent Application Publication
(10) Pub. No.: US 2025/0176415 A1
(43) Pub. Date: May 29, 2025

(54) ORGANIC LIGHT EMITTING DIODE DISPLAY DEVICE AND HEAD MOUNTED DISPLAY INCLUDING THE SAME

(71) Applicant: LG Display Co., Ltd., Seoul (KR)

(72) Inventors: Seungmin BAIK, Gimpo-si (KR); Sein SON, Seoul (KR); Kisuk KANG, Seoul (KR)

(73) Assignee: LG Display Co., Ltd., Seoul (KR)

(21) Appl. No.: 18/898,380

(22) Filed: Sep. 26, 2024

(30) Foreign Application Priority Data
Nov. 27, 2023 (KR) 10-2023-0166775

(51) Int. Cl. H10K 59/80

(52) U.S. Cl. CPC H10K 59/879; H10K 59/873; H10K 59/878

(57) ABSTRACT

Discussed is an organic light emitting diode display device including a substrate including a first sub-pixel, a second sub-pixel, and a third sub-pixel, a cathode electrode commonly disposed in the first sub-pixel, the second sub-pixel, and the third sub-pixel on the substrate, an encapsulation layer disposed on the cathode electrode, first lens structures disposed in boundary areas between the first to third sub-pixels on the encapsulation layer, and first to third color filters disposed in the first to third sub-pixels, respectively, on the encapsulation layer.

### CROSS REFERENCE TO RELATED APPLICATION

The present application claims priority to Korean Patent Application No. 10-2023-0166775, filed in the Republic of Korea on Nov. 27, 2023, the entire contents of which are hereby expressly incorporated by reference into the present application.

### BACKGROUND

### Field

The present disclosure relates to an organic light emitting diode display device, and a head mounted display device including the same.

### Discussion of the Related Art

Nowadays, there are various type of display devices, including liquid crystal display devices that can be used in portable devices. In this regards, organic light emitting diode display devices are also in demand since organic light emitting display devices are self-luminous types having a wider viewing angle and a higher contrast ratio than the liquid crystal display devices, and are even lighter and thinner than the liquid crystal display devices because the organic light emitting diode display devices have lower consumed power because the organic light emitting diode display devices do not require a separate backlight. In addition, the organic light emitting diode display devices have the advantages of being capable of DC low voltage driving, having a fast response time, and are becoming less expensive due to inexpensive manufacturing cost.

Recently, head mounted display devices including the organic light emitting diode display device have been developed. A head mounted display (HMD) device is an image display device that is worn on a user's head in the form of glasses or a helmet, for example, and focuses an image on a distance near the user's eyes. The head mounted display device can be used to implement virtual reality (VR) or augmented reality (AR) applications. For such applications, a high-resolution and small-sized organic light emitting diode display device can be applied to the head mounted display device.

### SUMMARY OF THE DISCLOSURE

In an organic light emitting diode display device, emission layers that emit light of different colors, such as red, green, and blue, for each sub-pixel can be formed individually, or an emission layer that emits light of a single color such as white can be commonly formed on all sub-pixels.

However, when the emission layer that emits light of a single color such as light of white is formed on all sub-pixels, a separate mask for forming the emission layer that emits light of different colors for each sub-pixel is not required, and thus a problem due to misalignment of a mask process, etc. doe not occur.

When the emission layer is formed to emit light of a single color such as light of white in all sub-pixels, a color filter should be additionally provided to implement different colors for each sub-pixel, and thus there is a disadvantage in that light emitted from light emitted from the emission layer is absorbed by the color filter to reduce light extraction efficiency.

In addition, in the case of high-resolution and small-sized organic light emitting diode display devices applied to head-mounted displays, the sizes of the sub-pixels are small at the sub-micron level, and thus there is a problem that it is difficult to form a sub-micron level black matrix made of an organic material between color filters.

Therefore, the inventors of the present disclosure have invented an organic light emitting diode display device including a structure that can prevent color mixing between sub-pixels and increase light extraction efficiency.

Embodiments of the present disclosure are directed to providing an organic light emitting diode display device in which color mixing between sub-pixels can be prevented and light extraction efficiency can be increased.

The objects of the present disclosure are not limited to the above-described objects, and other objects that are not mentioned will be able to be clearly understood by those skilled in the art from the following description.

An organic light emitting diode display device according to one embodiment of the present disclosure includes a substrate provided with a first sub-pixel, a second sub-pixel, and a third sub-pixel, a cathode electrode commonly disposed in the first sub-pixel, the second sub-pixel, and the third sub-pixel on the substrate, an encapsulation layer disposed on the cathode electrode, first lens structures disposed in boundary areas between the first to third sub-pixels on the encapsulation layer, and first to third color filters disposed in the first to third sub-pixels, respectively, on the encapsulation layer.

A head mounted display device according to one embodiment of the present disclosure includes left and right eyepieces, and left-eye and right-eye display devices configured to provide an image to the left and right eyepieces, wherein the left and right eyepieces include a substrate on which a first sub-pixel, a second sub-pixel, and a third sub-pixel are provided, a cathode electrode commonly disposed in the first sub-pixel, the second sub-pixel, and the third sub-pixel on the substrate, an encapsulation layer disposed on the cathode electrode, first lens structures disposed in boundary areas between the first to third sub-pixels on the encapsulation layer, and first to third color filters disposed in the first to third sub-pixels, respectively, on the encapsulation layer.

Detailed matters of other embodiments are included in a detailed description and accompanying drawings.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a schematic plan view of an organic light emitting diode display device according to one embodiment of the present disclosure.

FIG. 2 is a schematic cross-sectional view of the organic light emitting diode display device according to one embodiment of the present disclosure, which is a cross-sectional view along line 2-2 in FIG. 1.

FIG. 3 is an enlarged view of area 3 in FIG. 1.

FIG. 4 is a schematic cross-sectional view of an emission layer according to one embodiment of the present disclosure.

FIG. 5 is an enlarged view of a partial area of FIG. 1.

FIG. 6 is a schematic cross-sectional view of the organic light emitting diode display device according to one embodiment of the present disclosure.

FIG. 7 is a schematic cross-sectional view of the organic light emitting diode display device according to one embodiment of the present disclosure.

FIG. 8 is a schematic cross-sectional view of the organic light emitting diode display device according to one embodiment of the present disclosure.

FIG. 9 is a schematic cross-sectional view of the organic light emitting diode display device according to one embodiment of the present disclosure.

FIG. 10 is a schematic plan view of an organic light emitting diode display device according to one embodiment of the present disclosure.

FIG. 11 is a schematic cross-sectional view of the organic light emitting diode display device according to one embodiment of the present disclosure.

FIG. 12 is a schematic cross-sectional view of the organic light emitting diode display device according to one embodiment of the present disclosure.

FIG. 13 is a schematic cross-sectional view of the organic light emitting diode display device according to one embodiment of the present disclosure.

FIG. 14 is a schematic plan view of the organic light emitting diode display device according to one embodiment of the present disclosure.

FIGS. 15 to 17 show a head mounted display device according to one embodiment of the present disclosure.

### DETAILED DESCRIPTION OF THE EMBODIMENTS

Advantages and features of the present disclosure and methods for achieving them will become clear with reference to embodiments described below in detail in conjunction with the accompanying drawings. However, the present disclosure is not limited to the embodiments disclosed below but will be implemented in various different forms, these embodiments are merely provided to make the disclosure of the present disclosure complete and fully inform those skilled in the art to which the present disclosure pertains of the scope of the present disclosure.

Since shapes, sizes, ratios, angles, numbers, and the like disclosed in the drawings for describing the embodiments of the present disclosure are illustrative, the present disclosure is not limited to the illustrated items. The same reference number indicates the same components throughout the disclosure. In addition, in describing the present disclosure, when it is determined that the detailed description of a related known technology can unnecessarily obscure the gist of the present disclosure, detailed description thereof will be omitted. When terms “comprises,” “has,” “consists of,” and the like described in the present disclosure are used, other parts can be added unless “only” is used. When a component is expressed in the singular, it includes a case in which the component is provided as a plurality of components unless specifically stated otherwise.

In construing a component, the component is construed as including the margin of error even when there is no separate explicit description.

When the positional relationship is described, for example, when the positional relationship between two parts is described using the term “on,” “above,” “under,” “next to,” or the like, one or more other parts can be positioned between the two parts unless the term “immediately” or “directly” is used.

The term “can” fully encompasses all the meanings and coverages of the term “may.” The term “made of” for an element can fully encompass the meaning of being completely formed of the element, or simply including the element. In addition, the phrase “refractive indexes” which represent a plural form of “refractive index” is the same as and interchangeably used with “refractive indices.”

Although terms such as first and second are used to describe various components, the components are not limited by the terms. The terms are only used to distinguish one component from another. Therefore, a first component described below can be a second component within the technical spirit of the present disclosure.

The same reference number indicates the same components throughout the disclosure.

The size and thickness of each component shown in the drawings are shown for convenience of description, and the present disclosure is not necessarily limited to the sizes and thicknesses of the components shown.

Features of various embodiments of the present disclosure can be partially or fully coupled or combined, and as can be fully understood by those skilled in the art, various technical interconnection and operations are possible, and the embodiments can be implemented independently of each other and implemented together in combination thereof.

Hereinafter, an organic light emitting diode display device and a head mounted display device according to embodiments of the present disclosure will be described in detail with reference to the accompanying drawings.

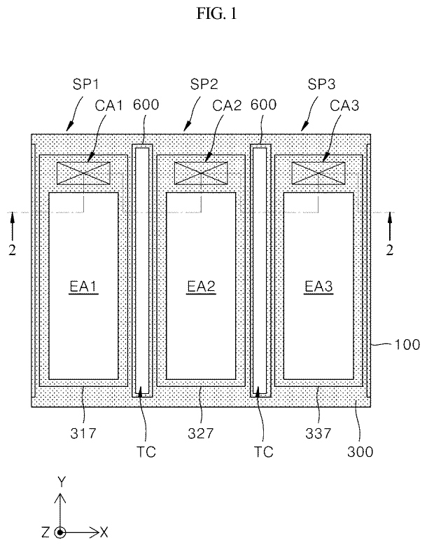

FIG. 1 is a schematic plan view of an organic light emitting diode display device according to one embodiment of the present disclosure. All components of each organic light emitting diode display apparatus according to all embodiments of the present disclosure are operatively coupled and configured.

In the organic light emitting diode display device according to one embodiment of the present disclosure, a plurality of sub-pixels SP1, SP2, and SP3 are disposed in a matrix form, and although only three sub-pixels SP1, SP2, and SP3 are shown in FIG. 1, embodiments of the present disclosure are not limited thereto, and any number of sub-pixels can be included in a pixel of a plurality of pixels.

Referring to FIG. 1, the organic light emitting diode display device according to one embodiment of the present disclosure includes a plurality of anode electrodes 317, 327, and 337, a trench TC, a lens structure 600, and a bank 300. But embodiments of the present disclosure are not limited thereto.

For example, the plurality of sub-pixels SP1, SP2, and SP3 arranged in an X-axis direction are provided on a substrate 100.

The plurality of emission areas EA1, EA2, and EA3 corresponding to the plurality of sub-pixels SP1, SP2, and SP3 are provided. The first sub-pixel SP1 has the first emission area EA1, the second sub-pixel SP2 has the second emission area EA2, and the third sub-pixel SP3 has the third emission area EA3.

The plurality of emission areas EA1, EA2, and EA3 are defined by the bank 300. Areas exposed without being covered by the bank 300 become the plurality of emission areas EA1, EA2, and EA3.

The plurality of anode electrodes 317, 327, and 337 corresponding to the plurality of sub-pixels SP1, SP2, and SP3 are provided. The first anode electrode 317 can be disposed in the first sub-pixel SP1, the second anode electrode 327 can be formed in the second sub-pixel SP2, and the third anode electrode 337 can be disposed in the third sub-pixel SP3. The first to third anode electrodes 317, 327, and 337 can be spaced apart from each other.

A portion of the first anode electrode 317 not covered by the bank 300 can be defined as the first emission area EA1. The first anode electrode 317 of the first sub-pixel SP1 can be connected to at least one transistor disposed on the substrate 100 through the first contact area CA1.

A portion of the second anode electrode 327 not covered by the bank 300 can be defined as the second emission area EA2. The second anode electrode 327 of the second sub-pixel SP2 can be connected to at least one transistor disposed on the substrate 100 through the second contact area CA2.

A portion of the third anode electrode 337 not covered by the bank 300 can be defined as the third emission area EA3. The third anode electrode 337 of the third sub-pixel SP3 can be connected to at least one transistor disposed on the substrate 100 through the third contact area CA3.

A trench TC extending in a Y-axis direction can be formed in boundary areas between the plurality of sub-pixels SP1, SP2, and SP3. The trench TC can be formed in the boundary area between the first sub-pixel SP1 and the second sub-pixel SP2, the boundary area between the second sub-pixel SP2 and the third sub-pixel SP3, and the boundary area between the third sub-pixel SP3 and the first sub-pixel SP1. But embodiments of the present disclosure are not limited thereto. In various embodiments of the present disclosure, the trench TC can encircle each of the plurality of sub-pixels SP1, SP2, and SP3 individually, or can encircle two or more of the plurality of sub-pixels SP1, SP2, and SP3 in groups. In other embodiments of the present disclosure, the trench TC can partially surround one or more of the plurality of sub-pixels SP1, SP2, and SP3. For example, the trench TC can be located in the boundary area between the first sub-pixel SP1 and the second sub-pixel SP2, and can also extend horizontally at a top and/or a bottom of the first sub-pixel SP1. Such an arrangement of the trench TC can be provided for the second sub-pixel SP2 and/or the third sub-pixel SP3. Additionally, such an arrangement of the trench TC can be provided relative to the first to third anode electrodes 317, 327, and 337, so that the trench TC can encircle or partially encircle one or more of the first to third anode electrodes 317, 327, and 337.A length of the trench TC in the Y-axis direction can be greater than lengths of the plurality of emission areas EA1, EA2, and EA3. The length of the trench TC in the Y-axis direction can be greater than or equal to lengths of the plurality of anode electrodes 317, 327, and 337. But embodiments of the present disclosure are not limited thereto, and the lengths of the trench TC in the Y-axis direction can be less than the lengths of the plurality of anode electrodes 317, 327 and 337. For example, the lengths of the trench TC in the Y-axis direction can be equal to or less than the lengths of the plurality of emission areas EA1, EA2, and EA3 in various embodiments of the present disclosure.

The lens structure 600 extending in the Y-axis direction is disposed in the boundary areas between the plurality of sub-pixels SP1, SP2, and SP3. The lens structure 600 can be disposed in the boundary area between the first sub-pixel SP1 and the second sub-pixel SP2, the boundary area between the second sub-pixel SP2 and the third sub-pixel SP3, and the boundary area between the third sub-pixel SP3 and the first sub-pixel SP1.

The lens structure 600 can include a portion that overlaps the trench TC and have a greater width than the trench TC. But embodiments of the present disclosure are not limited thereto. In other embodiments of the present disclosure, the width of the lens structure 600 can be equal to or less than the width of the trench TC. In various embodiments of the present disclosure, a width of a reflective core 620 of the lens structure 600 can be the same or different to the width of the trench TC. For example, the width of the reflective core 620 can be the less than or equal to the width of the trench TC.

A length of the lens structure 600 in the Y direction can be greater than lengths of the plurality of emission areas EA1, EA2, and EA3. The length of the lens structure 600 in the Y direction can be greater than the length of the trench TC. But embodiments of the present disclosure are not limited thereto.

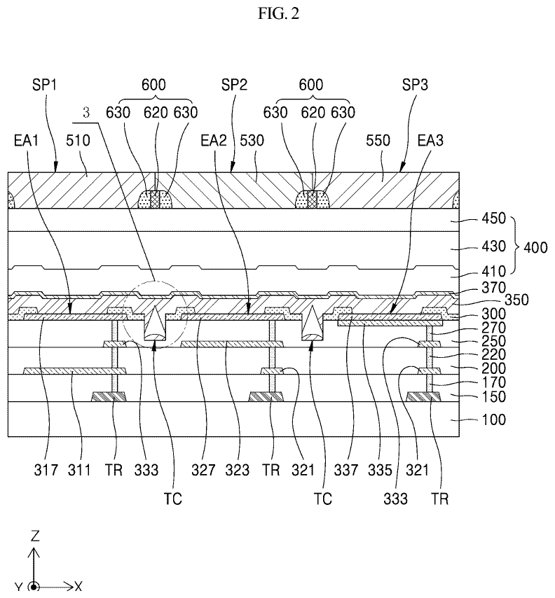

FIG. 2 is a schematic cross-sectional view of the organic light emitting diode display device according to one embodiment of the present disclosure, which is a cross-sectional view along line 2-2 in FIG. 1.

Referring to FIG. 2, the organic light emitting diode display device according to one embodiment of the present disclosure can include the substrate 100, a driving transistor TR, first to third insulating layers 150, 200, and 250, first to third reflective electrodes 311, 323, and 335, first and second contact electrodes 321 and 333, the first to third anode electrodes 317, 327, and 337, the bank 300, an emission layer 350, a cathode electrode 370, the trench TC, an encapsulation layer 400, the lens structure 600, and first to third color filters 510, 530, and 550. But embodiments of the present disclosure are not limited thereto. Additional layers or combined layers can be present.

The organic light emitting diode display device according to one embodiment of the present disclosure can be implemented in a so-called top emission type in which light emitted from the emission layer 350 is emitted upward.

The substrate 100 can be made of or include a semiconductor material such as a silicon wafer. In one embodiment, the substrate 100 can be made of or include glass or plastic. But embodiments of the present disclosure are not limited thereto.

For example, the first sub-pixel SP1, the second sub-pixel SP2, and the third sub-pixel SP3 arranged in the X-axis direction are provided on the substrate 100. The first sub-pixel SP1 can emit light of red, the second sub-pixel SP2 can emit light of green, and the third sub-pixel SP3 can emit light of blue. The arrangement order and direction of the sub-pixels SP1, SP2, and SP3 can be changed in any of various ways.

The driving circuit including various signal lines, thin film transistors, capacitors, etc. is provided on the substrate 100 for each of the sub-pixels SP1, SP2, and SP3. Signal lines can include gate lines, data lines, power lines, and reference lines, and transistors can include a switching transistor, a driving transistor TR, and a sensing thin film transistor. But embodiments of the present disclosure are not limited thereto. For example, the switching transistor, the driving transistor TR, and the sensing thin film transistor can be formed on the substrate 100 using a CMOS process. But embodiments of the present disclosure are not limited thereto.

The switching transistor is switched according to the gate signal supplied to the gate line to supply the data voltage supplied from the data line to the driving transistor.

The driving transistor TR is switched according to the data voltage supplied from the switching transistor to generate a data current from the power supplied from the power line and supply the data current to the anode electrodes 317, 327, and 337.

The sensing transistor serves to sense a threshold voltage difference of the driving transistor, which causes the degradation of image quality and supplies a current of the driving transistor to the reference line in response to a sensing control signal supplied from the gate line or a separate sensing line.

The capacitor serves to maintain the data voltage supplied to the driving transistor TR for one frame, and electrodes of the capacitor can be connected to a gate terminal and source terminal of the driving transistor TR, respectively.

The first insulating layer 150 can be disposed on the substrate 100. The first insulating layer 150 can be made of an inorganic insulating material or an organic insulating material. The first insulating layer 150 can cover transistors including driving transistors TR, various signal lines, capacitors, etc. which are disposed on the substrate 100.

The first reflective electrode 311 and the first contact electrodes 321 can be disposed on the first insulating layer 150. The first reflective electrode 311 can be disposed in the first sub-pixel SP1, and the first contact electrode 321 can be disposed in each of the second sub-pixel SP2 and the third sub-pixel SP3.

First contact vias 170 can be disposed to pass through the first corrugation formation layer 160 and the first insulating layer 150.

In the first to third sub-pixels SP1, SP2, and SP3, the first reflective electrode 311 and the first contact electrodes 321 can each be connected to the driving transistor TR through the first contact vias 170 passing through the first corrugation formation layer 160 and the first insulating layer 150.

After the first contact vias 170 passing through the first insulating layer 150 are first formed, the first reflective electrode 311 and the first contact electrodes 321 can be formed on the first insulating layer 150.

In one embodiment, the first reflective electrode 311 and the first contact via 170 can be formed integrally in the first sub-pixel SP1. The first contact electrode 321 and the first contact via 170 can be formed integrally in the second sub-pixel SP2. The first contact electrode 321 and the first contact via 170 can be formed integrally in the third sub-pixel SP3.

The first reflective electrode 311 and the first contact electrodes 321 can be made of a metal material with high reflectivity, such as silver (Ag), a silver alloy, aluminum (Al), or an aluminum alloy. The first contact via 170 can contain a metal material.

The second insulating layer 200 can be disposed on the first insulating layer 150, and the second insulating layer 200 can cover the first reflective electrode 311 and the first contact electrodes 321.

The second insulating layer 200 can be made of an inorganic insulating material or an organic insulating material.

The second reflective electrode 323 and the second contact electrodes 333 can be disposed on the second insulating layer 200.

The second reflective electrode 323 can be disposed in the second sub-pixel SP2, and the second contact electrode 333 can be disposed in each of the second sub-pixel SP1 and the third sub-pixel SP3.

Second contact vias 220 can be disposed to pass through the second insulating layer 200.

In the first sub-pixel SP1, the second contact electrode 333 can be connected to the first reflective electrode 311 through the second contact via 220 passing through the second insulating layer 200. In the second sub-pixel SP2, the second reflective electrode 323 can be connected to the first contact electrode 321 through the second contact via 220 passing through the second insulating layer 200. In the third sub-pixel SP3, the second contact electrode 333 can be connected to the first contact electrode 321 through the second contact via 220 passing through the second insulating layer 200.

The second reflective electrode 323 and the second contact electrodes 333 can be made of a metal material having high reflectivity, such as silver (Ag), a silver alloy, aluminum (Al), or an aluminum alloy. The second contact via 220 can contain a metal material.

After the second contact vias 220 passing through the second insulating layer 200 are first formed, the second reflective electrode 323 and the second reflective electrode 333 can be formed on the second insulating layer 200.

In one embodiment, the second reflective electrode 333 and the second contact via 220 can be formed integrally in the first sub-pixel SP1. The second reflective electrode 323 and the second contact via 220 can be formed integrally in the second sub-pixel SP2. The second contact electrode 333 and the second contact via 220 can be formed integrally in the third sub-pixel SP3.

The third insulating layer 250 can be disposed on the second insulating layer 200, and the third insulating layer 250 can cover the second reflective electrode 323 and the second contact electrodes 333.

The third insulating layer 250 can be made of an inorganic insulating material or an organic insulating material.

The first anode electrode 317, the second anode electrode 327, the third reflective electrode 335, the third anode electrode 337 can be disposed on the third insulating layer 250. The first anode electrode 317 can be disposed in the first sub-pixel SP1, the second anode electrode 327 can be disposed in the second sub-pixel SP2, and the third reflective electrode 335 and the third anode electrode 337 can be disposed in the third sub-pixel SP3.

The third reflective electrode 335 and the third anode electrode 337 can be in contact with each other and the third anode electrode 337 can be disposed on the third reflective electrode 335 in the third sub-pixel SP3.

Third contact vias 270 can be disposed to pass through the third insulating layer 250.

In the first sub-pixel SP1, the first anode electrode 317 can be connected to the second contact electrode 333 through the third contact via 270 passing through the third insulating layer 250. In the second sub-pixel SP2, the second anode electrode 327 can be connected to the second reflective electrode 323 through the third contact via 270 passing through the third insulating layer 250. In the third sub-pixel SP3, the third reflective electrode 335 can be connected to the second contact electrode 333 through the third contact via 270 passing through the third insulating layer 250.

In one embodiment, instead of the third reflective electrode 335 and the third anode electrode 337 being in contact with each other, an additional insulating layer can be further disposed on the third reflective electrode 335, and the first to third anodes electrodes 317, 327, and 337 can be disposed on the additional insulating layer. In this case, the third reflective electrode 335 and the third anode electrode 337 can be connected through an additional contact via passing through the additional insulating layer.

The third reflective electrode 335 can be made of a metal material with high reflectivity, such as silver (Ag), a silver alloy, aluminum (Al), or an aluminum alloy. The third contact via 270 can contain a metal material. The first to third anode electrodes 317, 327, and 337 can be made of a transparent conductive material such as ITO or IZO that can transmit light. But embodiments of the present disclosure are not limited thereto, and other materials can be used.

The first to third anode electrodes 317, 327, and 337 can each be electrically connected to the source terminal or drain terminal of the driving transistor disposed on the substrate 100.

The bank 300 can be disposed to cover the edge areas of the first to third anode electrodes 317, 327, and 337 on the third insulating layer 250. Portions of upper surfaces of the first to third anode electrodes 317, 327, and 337 exposed without being covered by the bank 300 become emission areas.

The bank 300 can be made of an inorganic insulating material. In one embodiment, the bank 300 can be made of an organic insulating material.

The trench TC having a concave structure is formed in the bank 300 and the third insulating layer 250. The trench TC can pass through the bank 300 in the boundary areas between the sub-pixels SP1, SP2, and SP3 and extend to a predetermined area of the third insulating layer 250. Therefore, the trench TC can be formed through a process of removing the bank 300 and the predetermined area of the third insulating layer 250. In one embodiment, the trench TC can extend to the inside of the second insulating layer 200 under the third insulating layer 250.

The trench TC is used to disconnect at least a portion of the emission layer 350. By disconnecting the at least a portion of the emission layer 350 in the trench TC, it is possible to prevent charges from moving between the neighboring sub-pixels SP1, SP2, and SP3 through the emission layer 350, thereby preventing the generation of a leakage current between the neighboring sub-pixels SP1, SP2, and SP3.

The emission layer 350 can be disposed in the emission areas EA1, EA2, and EA3 of the sub-pixels SP1, SP2, and SP3 and the boundary areas between the sub-pixels SP1, SP2, and SP3. The emission layer 350 can be disposed on the first to third anode electrodes 317, 327, and 337 and the bank 300 and can also be disposed inside and above the trench TC.

The emission layer 350 can be provided to emit white (W) light. To this end, the emission layer 350 can include a plurality of stacks that emit light of different colors. But embodiments of the present disclosure are not limited thereto, and the emission layer 350 can emit a desired color light other than white (W) light.

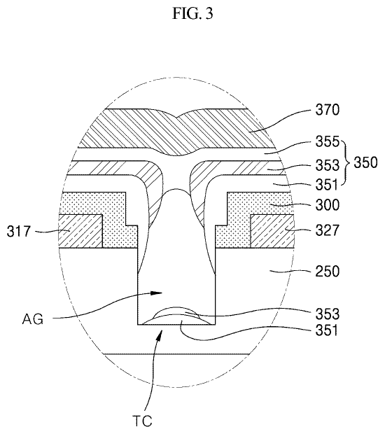

Referring to FIG. 3, the emission layer 350 can include a first stack 351, a second stack 355, and a charge generation layer CGL 353 provided between the first stack 351 and the second stack 355.

The emission layer 350 can be disposed inside and above the trench TC. When the emission layer 350 is disposed inside the trench TC, at least a portion of the emission layer 350 can be disconnected, thereby preventing the generation of the leakage current between the adjacent sub-pixels SP1, SP2, and SP3.

The first stack 351 can be disposed on side surfaces and a lower surface of the trench TC. In this case, a portion of the first stack 351 formed on the side surfaces of the trench TC and a portion of the first stack 351 formed on the lower surface of the trench TC are not connected. In addition, the portion of the first stack 351 formed on one side surface, such as a left side surface, of the trench TC and a portion of the first stack 351 formed on the other side surface, such as a right side surface, of the trench TC are not connected. Therefore, charges need not move between the sub-pixels SP1, SP2, and SP3 disposed adjacent to each other with the trench TC interposed therebetween through the first stack 351.

In addition, the charge generation layer 353 can be disposed on the first stack 351. In this case, the charge generation layer 353 need not extend to the inside of the trench TC and can be disposed only above the trench T. In addition, the charge generation layer 353 can also be disposed on the first stack 351 disposed on the lower surface of the trench TC.

In this case, a portion of the charge generation layer 353 formed on one side surface, such as the left side surface, of the trench TC and a portion of the charge generation layer 353 formed on the other side, such as the right side surface, of the trench TC are not connected. Therefore, charges need not move between the sub-pixels SP1, SP2, and SP3 disposed adjacent to each other with the trench TC interposed therebetween through the charge generation layer 353.

In addition, the second stack 355 can be connected between the sub-pixels SP1, SP2, and SP3 disposed adjacent to each other with the trench TC interposed therebetween on the charge generation layer 353. Therefore, charges can move between the sub-pixels SP1, SP2, and SP3 disposed adjacent to each other with the trench TC interposed therebetween through the second stack 355. However, by appropriately adjusting the shape of the trench TC and the deposition process of the emission layer 350, the second stack 355 can also be disconnected between the sub-pixels SP1, SP2, and SP3 disposed adjacent to each other with the trench TC interposed therebetween. In particular, a lower portion of the second stack 355 adjacent to the charge generation layer 353 can be disconnected in the areas between the sub-pixels SP1, SP2, and SP3.

An air gap AG can be formed in the trench T by the structures of the first stack 351, the charge generation layer 353, and the second stack 355. The air gap AG can be defined by the third insulating layer 250 and the emission layer 350. The air gap AG provided under the emission layer 350 can be defined by the third insulating layer 250, the first stack 351, the charge generation layer 353, and the second stack 355. The air gap AG can extend from the inside of the trench TC to the top of the trench TC. In various embodiments of the present disclosure, the air gap AG need not be filled with air but can be an empty space, a vacuumed space, or can be provided with one or more gases, or can be filled with a non-conductive material. Additionally, when the air gap AG is provided with air or a gas, a pressure in the air gap AG can be different from an atmospheric pressure.

The charge generation layer 353 has greater conductivity than the first stack 351 and the second stack 355. The charge generation layer 353 can include an n-type charge generation layer located adjacent to the first stack 351 and a p-type charge generation layer located adjacent to the second stack 355. This n-type charge generation layer can be an organic layer in which an organic host material capable of the electron transport ability is doped with an alkali metal such as Li, Na, K, or Cs or an alkaline earth metal such as Mg, Sr, Ba, or Ra, and the p-type charge generation layer can be made of an organic host material capable of the hole transport ability doped with a dopant.

As described above, since the n-type charge generation layer constituting the charge generation layer 353 can be made of a metal material, the n-type charge generation layer has greater conductivity than the first stack 351 and the second stack 355. Therefore, charges between the subpixels SP1, SP2, and SP3 disposed adjacent to each other are mainly moved through the charge generation layer 353.

In the organic light emitting diode display device according to one embodiment of the present disclosure, by forming a portion of the emission layer 350 to be disconnected in the trench TC when the emission layer 350 is formed in the trench TC, in particular, by forming the first stack 351 and the charge generation layer 353 to be disconnected in the trench TC, it is possible to prevent the generation of the leakage current between the adjacent sub-pixels SP1, SP2, and SP3. The trench TC and the surrounding components thereof according to FIG. 3 can also be applied to various embodiments to be described below.

The cathode electrode 370 is formed on the emission layer 350. Like the emission layer 350, the cathode electrode 370 can also be disposed in the emission areas EA1, EA2, and EA3 of the sub-pixels SP1, SP2, and SP3 and the boundary areas between the sub-pixels SP1, SP2, and SP3. The cathode electrode 370 is a common layer and can also be formed above the bank 300 and the trench TC.

The cathode electrode 370 can be made of a semi-transmissive conductive material. The cathode electrode 370 can be made of a metal material such as magnesium (Mg), silver (Ag), or an alloy of magnesium (Mg) and silver (Ag). The cathode electrode 370 can be formed in the form of a thin film having the thickness of several nanometers to tens of nanometers. Therefore, it is possible to obtain the micro cavity effect as light is repeatedly reflected and re-reflected between the cathode electrode 370 and the first to third reflective electrodes 317, 327, and 337.

According to one embodiment of the present disclosure, since the first distance between the first reflective electrode 311 and the cathode electrode 370 in the first sub-pixel SP1, the second distance between the second reflective electrode 323 and the cathode electrode 370 in the second sub-pixel SP2, and the third distance between the third reflective electrode 335 and the cathode electrode 370 in the third sub-pixel SP3 can all be configured differently, it is possible to increase light extraction efficiency of light of different colors, such as red, green, and blue light in the sub-pixels SP1, SP2, and SP3 by the micro cavity effect.

The encapsulation layer 400 is formed on the cathode electrode 370 to prevent the permeation of external moisture into the emission layer 350. The encapsulation layer 400 can include a first inorganic encapsulation layer 410 disposed on the cathode electrode 370, an organic encapsulation layer 430 disposed on the first inorganic encapsulation layer 410, and a second inorganic encapsulation layer 450 disposed on the organic encapsulation layer 430. The first and second inorganic encapsulation layers 410 and 450 can each be selected from aluminum oxide (AlₓO_{y}), silicon oxide (SiOₓ), silicon nitride (SiNₓ), silicon oxynitride (SiON), etc. The first and second inorganic encapsulation layers 410 and 450 can each have a refractive index of 1.7 to 1.9. But embodiments of the present disclosure are not limited thereto.

The lens structure 600 can be disposed in the boundary areas between the plurality of sub-pixels SP1, SP2, and SP3 on the encapsulation layer 400. Specifically, the lens structure 600 can be disposed in the boundary areas between the plurality of sub-pixels SP1, SP2, and SP3 on the second inorganic encapsulation layer 450 of the encapsulation layer 400. The lens structure 600 can be disposed in the boundary area between the first sub-pixel SP1 and the second sub-pixel SP2, the boundary area between the second sub-pixel SP2 and the third sub-pixel SP3, and the boundary area between the third sub-pixel SP3 and the first sub-pixel SP1.

The lens structure 600 can include a reflective core 620 and lenses 630 each disposed on both side surfaces of the reflective core.

Both side surfaces of the reflective core 620 can be, for example, substantially perpendicular to the upper surface of the encapsulation layer 400. Also, opposite side surfaces of the reflective core 620 can be parallel to each other, so that a width or a thickness of the reflective core 620 can be constant in a vertical direction. In one embodiment, the reflective core 620 can have a tapered shape whose width becomes narrower as it moves away from the upper surface of the encapsulation layer 400. Accordingly, a width or a thickness of the reflective core 620 can vary. When the width or the thickness of the reflective core 620 varies in moving away from the upper surface of the encapsulation layer 400, opposite side surfaces of the reflective core 620 can be curved. For example, the opposite side surfaces of the reflective core 620 can be convex, but embodiments of the present disclosure are not limited thereto, and the opposite side surfaces of the reflective core 620 can be concave, be sinusoidal or wavy, and a combination of convex and concave shapes. But embodiments of the present disclosure are not limited thereto.

The reflective core 620 can be made of a reflective material that can reflect light emitted from the emission layer 350. The reflective core 620 can include, for example, a metal material having high reflectivity. The reflective core 620 can include a metal material having high reflectivity, such as silver (Ag), silver alloy, aluminum (Al), or an aluminum alloy. But embodiments of the present disclosure are not limited thereto.

Each lens 630 has a narrower width as it moves away from the upper surface of the encapsulation layer 400, one side surface of each lens 630 can be in contact with the side surface of the reflective core 620, and the other side surface of each lens 630 can have a convex shape. But embodiments of the present disclosure are not limited thereto. In other embodiments of the present disclosure, outer surfaces of the lenses 630 that do not contact the reflective core 620 can be parallel to inner surfaces of the lenses 630 that contact the reflective core 620. Also, the outer surfaces of the lenses 630 need not be curved, but can be a flat surface. When the outer surfaces of the lenses 630 are flat, the outer surfaces of the lenses 630 can be located at a slant to an upper surface of the second inorganic encapsulation layer 450. In various embodiments of the present disclosure, the outer surfaces and the inner surfaces of the lenses 630 can be parallel when the outer surfaces and the inner surfaces of the lenses 630 slanted with respect to the uppers surface of the second inorganic encapsulation layer 450.

In one embodiment, each lens 630 can have a lower portion having a substantially constant width and an upper portion that has a narrower width as it moves away from the lower portion, the one side surface of each lens 630 can be in contact with a side surface of the reflective core 620, and the other side surface of each lens 630 can include a convex shape.

The lenses 630 can be made of an inorganic material. The lenses 630 can have a lower refractive index than the second inorganic encapsulation layer 450. In addition, the lenses 630 can have a lower refractive index than the first to third color filters 510, 530, and 550. The lenses 630 can have, for example, a refractive index of about 1.3 to 1.5. The lenses 630 can include, for example, silicon oxide (SiOₓ) or magnesium fluoride (MgF₂). But embodiments of the present disclosure are not limited thereto. Other materials such as resin, Al₂O₃, or glass can also be used. In various embodiments of the present disclosure, the lenses 630 can be transparent. Also, in various embodiments of the present invention, the lenses 630 can have a color, whereby the color of the lenses 630 can be the same or match a corresponding one of the color filters 510, 530, and 550. Therefore, the lenses 630 located adjacent the blue color filter 550 can include a blue color while the lenses 630 located adjacent the green color filter 530 can include a green color, and so on.

With reference to FIG. 2, a height (or a thickness in a vertical direction) of the lens structure 600 can be different from a height or a thickness of a layer covering the lens structure 600, such as one or more of the first to third color filters 510, 530, and 550. For example, the height of the lens structure 600 can be less than that of the first to third color filters 510, 530, and 550, but embodiments of the present disclosure are not limited thereto, and the height of the lens structure 600 can be greater than or equal to that of the first to third color filters 510, 530, and 550. Additionally, a height (or a thickness in a vertical direction) of individual components of lens structure 600, such as the reflective core 620 and the lenses 630 can be respectively different from the height or a thickness of the layer covering the lens structure 600, such as the one or more of the first to third color filters 510, 530, and 550. In this regard, the height of the reflective core 620 and the height of the lenses 630 can be the same or different. When the height of the lenses 630 are greater than that of the reflective core 620, a portion of the lenses 630 can cover an upper portion of the reflective core 620, but embodiments of the present disclosure are not limited thereto. For example, in various embodiments, the upper portion of the reflective core 620 can be exposed by the lenses 630, so that a gap is provided over the upper portion of the reflective core 620.

On the other hand, when the height of the lenses 630 are less than that of the reflective core 620, a portion of the lenses 630 can be lower than the upper portion of the reflective core 620, but embodiments of the present disclosure are not limited thereto. For example, in various embodiments, the upper portion of the reflective core 620 can be exposed by the lenses 630 and protrude upward.

The first to third color filters 510, 530, and 550 can be disposed on the encapsulation layer 400. The red color filter 510 overlapping the first emission area EA1 can be provided in the first sub-pixel SP1, the green color filter 530 overlapping the second emission area EA2 can be provided in the second sub-pixel SP2, and the blue color filter 550 overlapping the third emission area EA3 can be provided in the third sub-pixel SP3. The first color filter 510 can be a red color filter that emits light of red, the second color filter 530 can be a green color filter that emits light of green, and the third color filter 550 can be a blue color filter that emits light of blue.

Edge portions of the first to third color filters 510, 530, and 550 can cover the lenses 630 of the lens structures 600.

The refractive indexes of the first to third color filters 510, 530, and 550 can be greater than the refractive indexes of the lenses 630 of the lens structures 600. The first to third color filters 510, 530, and 550 can each have a refractive index of 1.7 to 1.9. In the present specification, the phrase “refractive indexes” which represent a plural form of “refractive index” is the same as and interchangeably used with “refractive indices.”

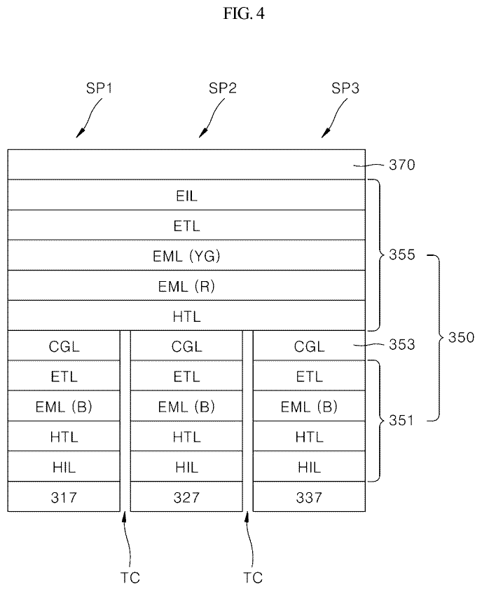

FIG. 4 is a schematic cross-sectional view of emission layers disposed in sub-pixels according to one embodiment of the present disclosure.

Referring to FIG. 4, the first anode electrode 317 is disposed in the first sub-pixel SP1, the second anode electrode 327 is disposed in the second sub-pixel SP2, and the third anode electrode 337 is disposed in the third sub-pixel SP3.

The emission layer 350 is disposed on the first to third anode electrodes 317, 327, and 337. The emission layer 350 includes the first stack 351, the second stack 355, and the charge generation layer CGL 353.

The first stack 351 can be formed in a structure in which a hole injecting layer HIL, a hole transporting layer HTL, a blue emitting layer EML(B), and an electron transporting layer ETL are stacked sequentially. The first stack 351 is disconnected in the boundary areas between the sub-pixels SP1, SP2, and SP3, for example, the trench TC areas. But embodiments of the present disclosure are not limited thereto.

The charge generation layer CGL 353 serves to supply charges to the first stack 351 and the second stack 355. The charge generation layer CGL 353 can include an n-type charge generation layer for supplying electrons to the first stack 351 and a p-type charge generation layer for supplying holes to the second stack 355. As described above, the n-type charge generation layer can include a metal material as a dopant. The charge generation layer 720 is disconnected in the boundary areas between the sub-pixels SP1, SP2, and SP3, for example, the trench TC areas.

The second stack 355 can be provided on the charge generation layer CGL 353 and formed in a structure in which the hole transporting layer HTL, a red emitting layer EML(R), a yellow green emitting layer EML(YG), the electron transporting layer ETL, and the electron injecting layer EIL are stacked sequentially. The stacking order of the red emitting layer EML(R) and the yellow green emitting layer EML(YG) can be changed.

The second stack 355 can be disposed to be connected between the sub-pixels SP1, SP2, and SP3. However, as described above, the lower portion of the second stack 355 can be disconnected in the boundary areas between the sub-pixels P1, P2, and P3, for example, the trench TC areas. For example, the hole transporting layer HTL of the second stack 355 can be disconnected, or the hole transporting layer HTL and the red emitting layer EML(R) of the second stack 355 can be disconnected. For example, the hole transporting layer HTL, the red emitting layer EML(R), and the yellow green emitting layer EML(YG) of the second stack 355 can be disconnected. But embodiments of the present disclosure are not limited thereto.

The cathode electrode 370 is disposed on the emission layer 350. The cathode electrode 370 can be formed to be connected between the sub-pixels SP1, SP2, and SP3.

The emission layer 350 of FIG. 4 emits white light in a combination of the blue emitting layer EML(B) of the first stack 351 and the red emitting layer EML(R) and the yellow green emitting layer EML(YG) of the second stack 355.

In one embodiment, the second stack 355 can include only the yellow green emitting layer EML(YG). In this case, white light is emitted in a combination of the blue emitting layer EML(B) of the first stack 351 and the yellow green emitting layer EML(YG) of the second stack 355.

In one embodiment, the green emitting layer EML(G) can be formed instead of the yellow green emitting layer EML(YG) of the second stack 355. In this case, the emission layer 350 emits white light in a combination of the blue emitting layer EML(B) of the first stack 351 and the red emitting layer EML(R) and green emitting layer EML(G) of the second stack 355.

In one embodiment, the first stack 351 can include the red emitting layer EML(R) and the yellow green emitting layer EML(YG), and the second stack 355 can include the blue emitting layer EML(B). In one embodiment, the first stack 351 can include the red emitting layer EML(R) and the green emitting layer EML(G), and the second stack 355 can include the blue emitting layer EML(B).

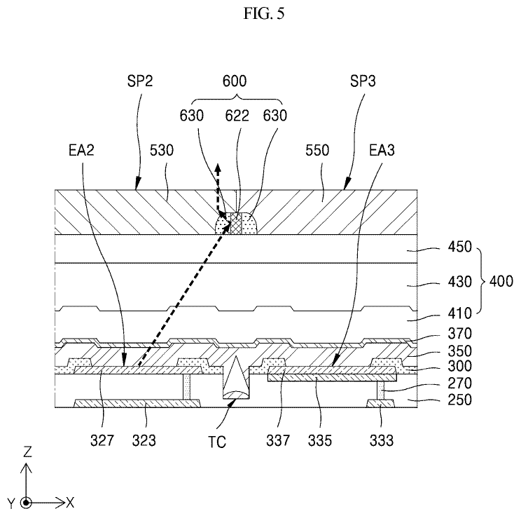

FIG. 5 is an enlarged view of area 5 in FIG. 1. FIG. 5 is an enlarged view of portions of the second sub-pixel SP2 and the third sub-pixel SP3 to describe the prevention of color mixing between the sub-pixels and an increase in light extraction efficiency in the organic light emitting diode display device according to one embodiment of the present disclosure.

Referring to FIG. 5, for example, light emitted obliquely from the emission layer 350 of the second sub-pixel SP2 and facing the third color filter 550 of the third sub-pixel SP3 is incident on the lens structure 600, the light incident on the lens structure 600 is reflected by side surfaces of a reflective core 622. In this case, since the refractive index of the lens 630 having the convex shape is lower than that of the second color filter 530, the light reflected by side surfaces of the reflective core 622 can be refracted by the lens 630 and emitted in the forward direction. But embodiments of the present disclosure are not limited thereto.

Similarly, when the light emitted obliquely from the emission layer 350 of the third sub-pixel SP3 and facing the second color filter 530 of the second sub-pixel SP2 is incident on the lens structure 600, the light is reflected by the reflective core 622 of the lens structure 600, then refracted by the lens 630, and emitted in the forward direction.

As described above, by arranging the lens structures 600 in the boundary areas between the first to third sub-pixels SP1, SP2, and SP3 and setting the refractive indexes of the lenses 630 of the lens structure 600 to be lower than the refractive indexes of the first to third color filters 510, 530, and 550, the light emitted from one sub-pixel can be blocked from proceeding to another adjacent sub-pixel, and at the same time, the light incident on the lens structure 600 can be emitted in the forward direction Therefore, it is possible to prevent color mixing between the sub-pixels of the organic light emitting diode display device and increase light extraction efficiency.

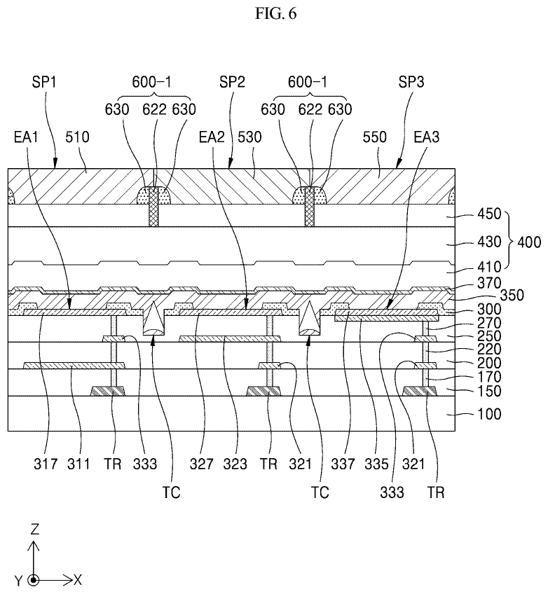

FIG. 6 is a schematic cross-sectional view of the organic light emitting diode display device according to one embodiment of the present disclosure.

FIG. 6 corresponds to a cross-sectional view along line 2-2 in FIG. 1. The organic light emitting diode display device shown in FIG. 6 differs from the organic light emitting diode display device shown in FIG. 2 in that a lens structure 600-1 is provided instead of the lens structure 600. Therefore, in the following description of the organic light emitting diode display device shown in FIG. 6, only the configuration that differs from that of the organic light emitting display device shown in FIG. 2 will be described.

Referring to FIG. 6, the lens structure 600-1 disposed on the encapsulation layer 400 can include the reflective core 622 and the lenses 630 each disposed on both side surfaces of the reflective core.

The reflective core 622 can extend to the inside of the second inorganic encapsulation layer 450. A lower surface of the reflective core 622 can be in contact with the organic encapsulation layer 430. In one embodiment, the lower surface of the reflective core 622 can be located in the second inorganic encapsulation layer 450. In one embodiment, the lower surface of the reflective core 622 can extend to the inside of the organic encapsulation layer 430.

The lenses 630 can be disposed on an upper surface of the second inorganic encapsulation layer 450.

The reflective core 622 can be made of a reflective material that can reflect light emitted from the emission layer 350. The reflective core 622 can include, for example, a metal material having high reflectivity. The reflective core 622 can include a metal material having high reflectivity, such as silver (Ag), silver alloy, aluminum (Al), or an aluminum alloy. But embodiments of the present disclosure are not limited thereto.

As described above, by arranging the lens structures 600 in the boundary areas between the first to third sub-pixels SP1, SP2, and SP3 and setting the refractive indexes of the lenses 630 of the lens structure 600 to be lower than the refractive indexes of the first to third color filters 510, 530, and 550, the light emitted from one sub-pixel can be blocked from proceeding to another adjacent sub-pixel, and at the same time, the light incident on the lens structure 600-1 can be emitted in the forward direction. Therefore, it is possible to prevent color mixing between the sub-pixels of the organic light emitting diode display device and increase light extraction efficiency.

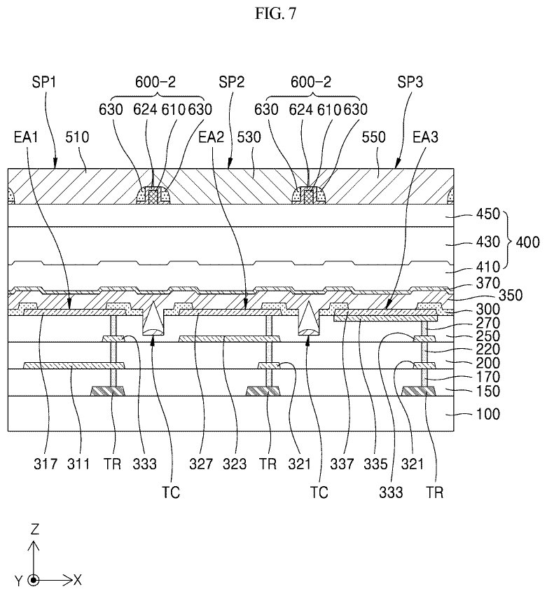

FIG. 7 is a schematic cross-sectional view of the organic light emitting diode display device according to one embodiment of the present disclosure.

FIG. 7 corresponds to a cross-sectional view along line 2-2 in FIG. 1. The organic light emitting diode display device shown in FIG. 7 differs from the organic light emitting diode display device shown in FIG. 2 in that a lens structure 600-2 is provided instead of the lens structure 600. Therefore, in the following description of the organic light emitting diode display device shown in FIG. 7, only the configuration that differs from that of the organic light emitting display device shown in FIG. 2 will be described.

Referring to FIG. 7, the lens structure 600-1 disposed on the encapsulation layer 400 can include a core 610, a reflective layer 624 covering at least both side surfaces of the core 610, and the lens 630 disposed at each of both sides of the core 610 and in contact with the reflective layer 624.

As shown in FIG. 7, the reflective layer 624 can cover the upper surface and both side surfaces of the core 610, can be disposed between the lenses 630 and the core 610, and can extend to a space between the lenses 630 and the encapsulation layer 400. In one embodiment, the reflective layer 624 can be formed to not cover an upper surface of the core 610. But embodiments of the present disclosure are not limited thereto.

The lenses 630 can be disposed on the reflective layer 624.

The core 610 can be made of, for example, an inorganic material. But embodiments of the present disclosure are not limited thereto, and other materials can be used.

The reflective layer 624 can be made of a reflective material capable of reflecting the light emitted from the emission layer 350. The reflective layer 624 can include, for example, a metal material having high reflectivity. The reflective layer 624 can include a metal material having high reflectivity, such as silver (Ag), silver alloy, aluminum (Al), or an aluminum alloy. But embodiments of the present disclosure are not limited thereto.

As described above, by arranging the lens structures 600 in the boundary areas between the first to third sub-pixels SP1, SP2, and SP3 and setting the refractive indexes of the lenses 630 of the lens structure 600 to be lower than the refractive indexes of the first to third color filters 510, 530, and 550, the light emitted from one sub-pixel can be blocked from proceeding to another adjacent sub-pixel, and at the same time, the light incident on the lens structure 600-2 can be emitted in the forward direction Therefore, it is possible to prevent color mixing between the sub-pixels of the organic light emitting diode display device and increase light extraction efficiency.

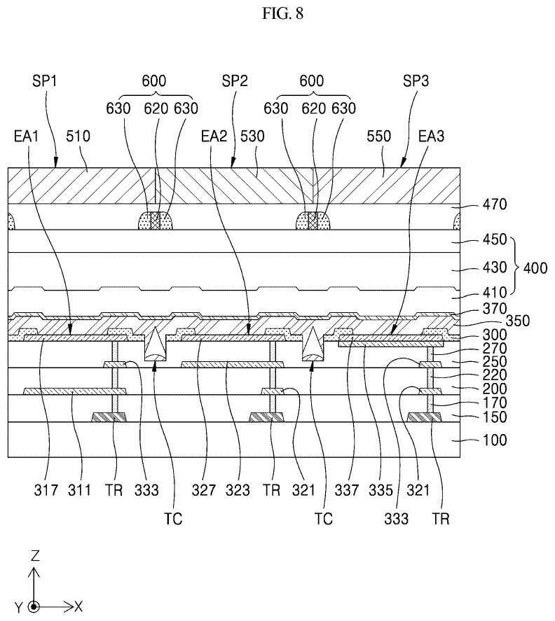

FIG. 8 is a schematic cross-sectional view of the organic light emitting diode display device according to one embodiment of the present disclosure.

FIG. 8 corresponds to a cross-sectional view along line 2-2 in FIG. 1. The organic light emitting diode display device shown in FIG. 8 differs from the organic light emitting diode display device shown in FIG. 2 in that a planarization layer 470 covering the lens structure 600 is further provided. Therefore, in the following description of the organic light emitting diode display device shown in FIG. 8, only the configuration that differs from that of the organic light emitting display device shown in FIG. 2 will be described.

Referring to FIG. 8, the planarization layer 470 covering the lens structure 600 can be disposed on the encapsulation layer 400.

The first to third color filters 510, 530, and 550 can be disposed on the planarization layer 470.

A refractive index of the planarization layer 470 can be greater than the refractive indexes of the lenses 630 of the lens structure 600. The planarization layer 470 can have a refractive index of 1.7 to 1.9. The planarization layer 470 can be made of, for example, an organic material. But embodiments of the present disclosure are not limited thereto.

For example, when the light emitted obliquely from the emission layer 350 of the second sub-pixel SP2 and facing the third color filter 550 of the third sub-pixel SP3 is incident on the lens structure 600, the light incident on the lens structure 600 is reflected by side surfaces of the reflective core 622. In this case, since the refractive index of the lens 630 having the convex shape is lower than that of the second planarization layer 470, the light reflected by the side surfaces of the reflective core 622 can be refracted by the lens 630 and emitted in the forward direction.

As described above, by arranging the lens structures 600 in the boundary areas between the first to third sub-pixels SP1, SP2, and SP3 and covering the lens structures 600 with the planarization layer 470 having a greater refractive index than the lenses 630 of the lens structures 600, the light emitted from one sub-pixel can be blocked from proceeding to another adjacent sub-pixel, and at the same time, the light incident on the lens structure 600 can be emitted in the forward direction. Therefore, it is possible to prevent color mixing between the sub-pixels of the organic light emitting diode display device and increase light extraction efficiency.

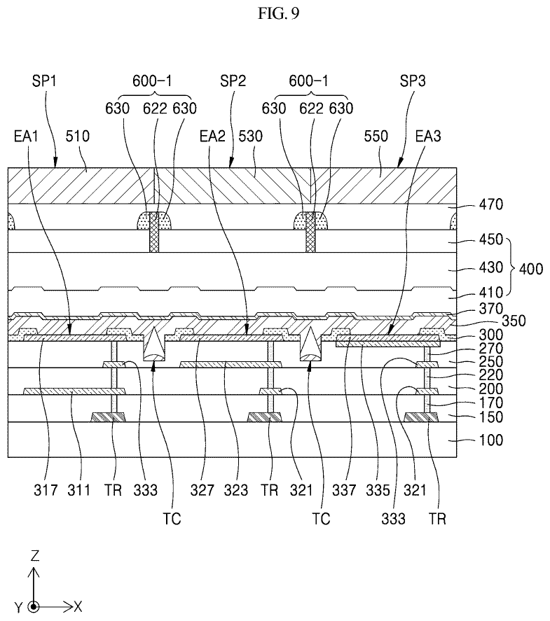

FIG. 9 is a schematic cross-sectional view of the organic light emitting diode display device according to one embodiment of the present disclosure.

FIG. 9 corresponds to a cross-sectional view along line 2-2 in FIG. 1. The organic light emitting diode display device shown in FIG. 9 differs from the organic light emitting diode display device shown in FIG. 6 in that the planarization layer 470 covering the lens structure 600-1 is further provided. Therefore, in the following description of the organic light emitting diode display device shown in FIG. 9, only the configuration that differs from that of the organic light emitting display device shown in FIG. 6 will be described.

Referring to FIG. 9, the planarization layer 470 covering the lens structure 600-1 can be disposed on the encapsulation layer 400.

The first to third color filters 510, 530, and 550 can be disposed on the planarization layer 470.

The refractive index of the planarization layer 470 can be greater than the refractive indexes of the lenses 630 of the lens structure 600-1. The planarization layer 470 can have a refractive index of 1.7 to 1.9. The planarization layer 470 can be made of, for example, an organic material. But embodiments of the present disclosure are not limited thereto.

As described above, by arranging the lens structures 600-1 in the boundary areas between the first to third sub-pixels SP1, SP2, and SP3 and covering the lens structures 600-1 with the planarization layer 470 having a greater refractive index than the lenses 630 of the lens structures 600-1, the light emitted from one sub-pixel can be blocked from proceeding to another adjacent sub-pixel, and at the same time, the light incident on the lens structure 600-1 can be emitted in the forward direction. Therefore, it is possible to prevent color mixing between the sub-pixels of the organic light emitting diode display device and increase light extraction efficiency. Also, the core 622 extends into the 450.

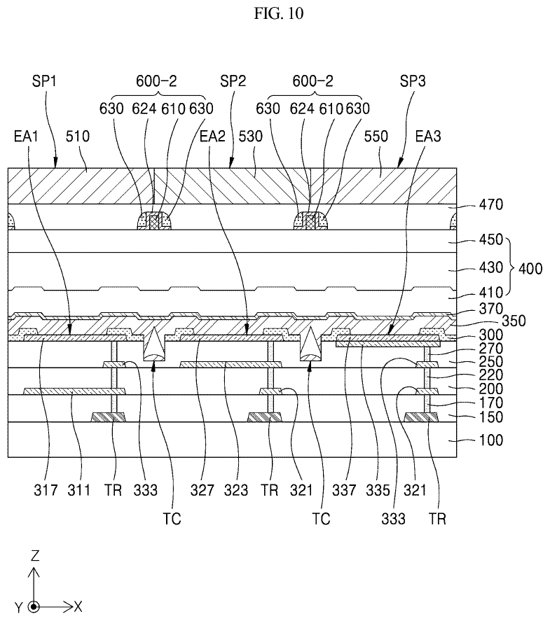

FIG. 10 is a schematic cross-sectional view of the organic light emitting diode display device according to one embodiment of the present disclosure.

FIG. 10 corresponds to a cross-sectional view along line 2-2 in FIG. 1. The organic light emitting diode display device shown in FIG. 10 differs from the organic light emitting diode display device shown in FIG. 7 in that the planarization layer 470 covering the lens structure 600-2 is further provided. Therefore, in the following description of the organic light emitting diode display device shown in FIG. 10, only the configuration that differs from that of the organic light emitting display device shown in FIG. 7 will be described.

Referring to FIG. 10, the planarization layer 470 covering the lens structure 600-2 can be disposed on the encapsulation layer 400.

The first to third color filters 510, 530, and 550 can be disposed on the planarization layer 470.

The refractive index of the planarization layer 470 can be greater than the refractive indexes of the lenses 630 of the lens structure 600-2. The planarization layer 470 can have a refractive index of 1.7 to 1.9. The planarization layer 470 can be made of, for example, an organic material. But embodiments of the present disclosure are not limited thereto.

As described above, by arranging the lens structures 600-2 in the boundary areas between the first to third sub-pixels SP1, SP2, and SP3 and covering the lens structures 600-2 with the planarization layer 470 having a greater refractive index than the lenses 630 of the lens structures 600-2, the light emitted from one sub-pixel can be blocked from proceeding to another adjacent sub-pixel, and at the same time, the light incident on the lens structure 600-2 can be emitted in the forward direction. Therefore, it is possible to prevent color mixing between the sub-pixels of the organic light emitting diode display device and increase light extraction efficiency. Also, the 624 is provided.

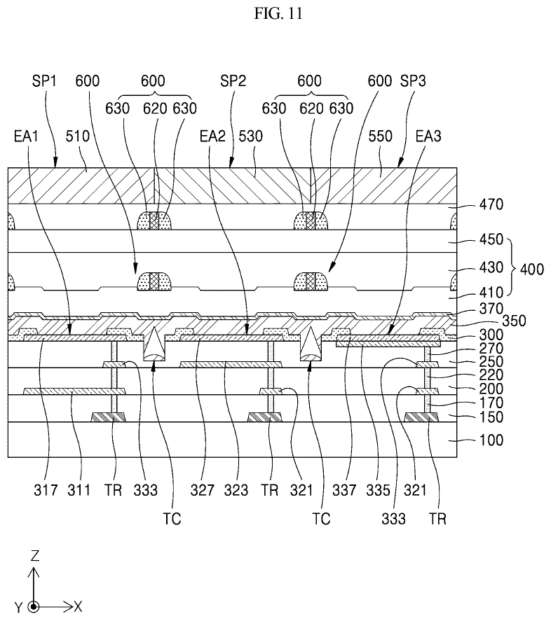

FIG. 11 is a schematic cross-sectional view of the organic light emitting diode display device according to one embodiment of the present disclosure.

FIG. 11 corresponds to a cross-sectional view along line 2-2 in FIG. 1. The organic light emitting diode display device shown in FIG. 11 differs from the organic light emitting diode display device shown in FIG. 8 in that the lens structure 600 is further provided between the first inorganic encapsulation layer 410 and the organic encapsulation layer 430. Therefore, in the following description of the organic light emitting diode display device shown in FIG. 11, only the configuration that differs from that of the organic light emitting display device shown in FIG. 8 will be described.

Referring to FIG. 11, the lens structures 600 can be further disposed in the boundary areas between the first to third sub-pixels SP1, SP2, and SP3 on the first inorganic encapsulation layer 410 of the encapsulation layer 400. The organic encapsulation layer 430 can cover the lens structures 600.

The lens structures 600 disposed between the first inorganic encapsulation layer 410 and the organic encapsulation layer 430 can be arranged to overlap the lens structures 600 disposed on the second inorganic encapsulation layer 450.

The lens structure 600 disposed on the second inorganic encapsulation layer 450 can be referred to as a first lens structure or an upper lens structure, and the lens structures 600 disposed between the first inorganic encapsulation layer 410 and the organic encapsulation layer 430 can be referred to as a second lens structure or a lower lens structure.

A refractive index of the organic encapsulation layer 430 can be greater than the refractive indexes of the lenses 630 of the lens structure 600. The organic encapsulation layer 430 can have a refractive index of 1.7 to 1.9. The organic encapsulation layer 430 can be made of an organic material.

As described above, by arranging the first lens structures 600 and the second lens structures 600 in the boundary areas between the first to third sub-pixels SP1, SP2, and SP3 and setting the refractive indexes of the lenses 630 to be smaller than the refractive index of the material covering the lenses 630, it is possible to prevent color mixing between the sub-pixels of the organic light emitting diode display device and increase light extraction efficiency.

In one embodiment, the planarization layer 470 can be removed from the organic light emitting diode display device shown in FIG. 11, and the color filters 510, 530, and 550 can be directly disposed to cover the lens structures 600 on the encapsulation layer 400.

In one embodiment, in the organic light emitting diode display device shown in FIG. 11, the lens structure 600-1 or the lens structure 600-2 instead of the lens structures 600 can be disposed between the first inorganic encapsulation layer 410 and the organic encapsulation layer 430.

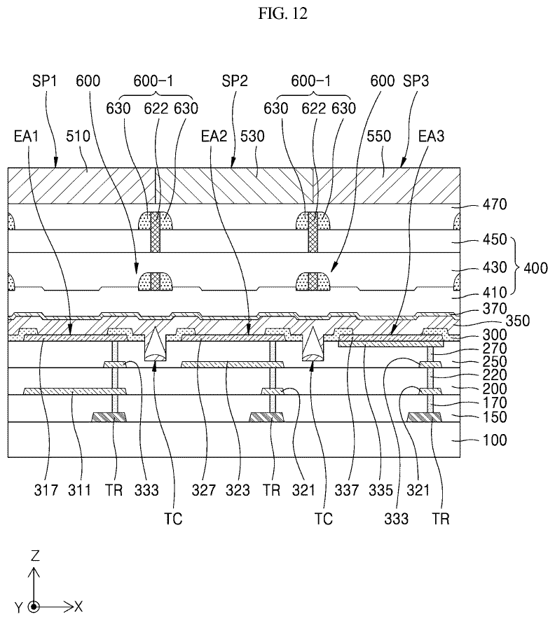

FIG. 12 is a schematic cross-sectional view of the organic light emitting diode display device according to one embodiment of the present disclosure.

FIG. 12 corresponds to a cross-sectional view along line 2-2 in FIG. 1. The organic light emitting diode display device shown in FIG. 12 differs from the organic light emitting diode display device shown in FIG. 9 in that the lens structure 600 is further provided between the first inorganic encapsulation layer 410 and the organic encapsulation layer 430. Therefore, in the following description of the organic light emitting diode display device shown in FIG. 12, only the configuration that differs from that of the organic light emitting display device shown in FIG. 9 will be described.

Referring to FIG. 12, the lens structures 600 can be further disposed in the boundary areas between the first to third sub-pixels SP1, SP2, and SP3 on the first inorganic encapsulation layer 410 of the encapsulation layer 400. The organic encapsulation layer 430 can cover the lens structures 600.

The lens structures 600 disposed between the first inorganic encapsulation layer 410 and the organic encapsulation layer 430 can be arranged to overlap the lens structures 600-1 disposed on the second inorganic encapsulation layer 450.

The lens structure 600-1 disposed on the second inorganic encapsulation layer 450 can be referred to as a first lens structure or an upper lens structure, and the lens structures 600 disposed between the first inorganic encapsulation layer 410 and the organic encapsulation layer 430 can be referred to as a second lens structure or a lower lens structure.

The refractive index of the organic encapsulation layer 430 can be greater than the refractive indexes of the lenses 630 of the lens structure 600. The organic encapsulation layer 430 can have a refractive index of 1.7 to 1.9. The organic encapsulation layer 430 can be made of an organic material.

As described above, by arranging the first lens structures 600-1 and the second lens structures 600 in the boundary areas between the first to third sub-pixels SP1, SP2, and SP3 and setting the refractive indexes of the lenses 630 to be smaller than the refractive index of the material covering the lenses 630, it is possible to prevent color mixing between the sub-pixels of the organic light emitting diode display device and increase light extraction efficiency.

In one embodiment, the planarization layer 470 can be removed from the organic light emitting diode display device shown in FIG. 12, and the color filters 510, 530, and 550 can be directly disposed to cover the lens structures 600-1 on the encapsulation layer 400.

In one embodiment, in the organic light emitting diode display device shown in FIG. 12, the lens structure 600-1 or the lens structure 600-2 instead of the lens structures 600 can be disposed between the first inorganic encapsulation layer 410 and the organic encapsulation layer 430.

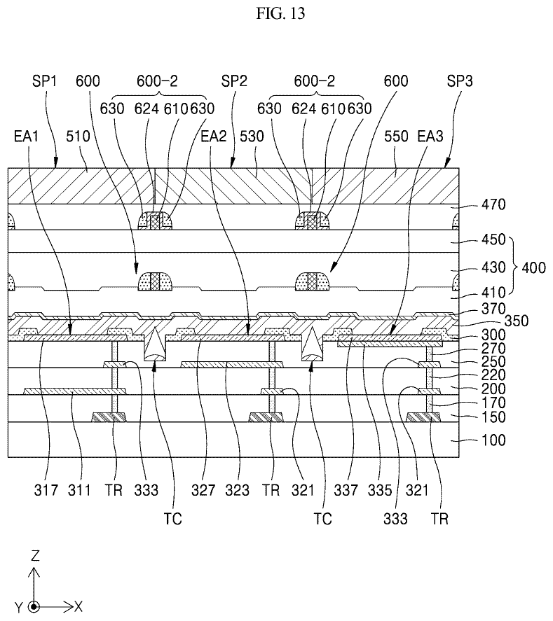

FIG. 13 is a schematic cross-sectional view of the organic light emitting diode display device according to one embodiment of the present disclosure.

FIG. 13 corresponds to a cross-sectional view along line 2-2 in FIG. 1. The organic light emitting diode display device shown in FIG. 13 differs from the organic light emitting diode display device shown in FIG. 10 in that the lens structure 600 is further provided between the first inorganic encapsulation layer 410 and the organic encapsulation layer 430. Therefore, in the following description of the organic light emitting diode display device shown in FIG. 13, only the configuration that differs from that of the organic light emitting display device shown in FIG. 10 will be described.

Referring to FIG. 13, the lens structures 600 can be further disposed in the boundary areas between the first to third sub-pixels SP1, SP2, and SP3 on the first inorganic encapsulation layer 410 of the encapsulation layer 400. The organic encapsulation layer 430 can cover the lens structures 600.

The lens structures 600 disposed between the first inorganic encapsulation layer 410 and the organic encapsulation layer 430 can be arranged to overlap the lens structures 600-2 disposed on the second inorganic encapsulation layer 450.

The lens structures 600-2 disposed on the second inorganic encapsulation layer 450 can be referred to as a first lens structure or an upper lens structure, and the lens structures 600 disposed between the first inorganic encapsulation layer 410 and the organic encapsulation layer 430 can be referred to as a second lens structure or a lower lens structure.

The refractive index of the organic encapsulation layer 430 can be greater than the refractive indexes of the lenses 630 of the lens structure 600. The organic encapsulation layer 430 can have a refractive index of 1.7 to 1.9. The organic encapsulation layer 430 can be made of an organic material.

As described above, by arranging the first lens structures 600-2 and the second lens structures 600 in the boundary areas between the first to third sub-pixels SP1, SP2, and SP3 and setting the refractive indexes of the lenses 630 to be smaller than the refractive index of the material covering the lenses 630, it is possible to prevent color mixing between the sub-pixels of the organic light emitting diode display device and increase light extraction efficiency.

In one embodiment, the planarization layer 470 can be removed from the organic light emitting diode display device shown in FIG. 13, and the color filters 510, 530, and 550 can be directly disposed to cover the lens structures 600-2 on the encapsulation layer 400.

In one embodiment, in the organic light emitting diode display device shown in FIG. 13, the lens structure 600-1 or the lens structure 600-2 instead of the lens structures 600 can be disposed between the first inorganic encapsulation layer 410 and the organic encapsulation layer 430.

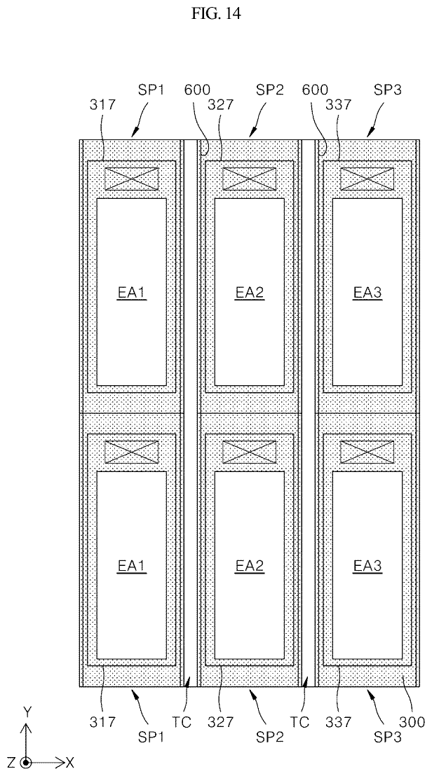

FIG. 14 is a schematic plan view of the organic light emitting diode display device according to one embodiment of the present disclosure. In the organic light emitting diode display device according to one embodiment of the present disclosure, the plurality of sub-pixels SP1, SP2, and SP3 are disposed in a matrix form, but only six sub-pixels SP1, SP2, and SP3 are shown in FIG. 14.

Referring to FIG. 14, the organic light emitting diode display device according to one embodiment of the present disclosure includes the plurality of anode electrodes 317, 327, and 337, the trench TC, the lens structure 600, and the bank 300.

For example, the plurality of sub-pixels SP1, SP2, and SP3 arranged in the X-axis and Y-axis directions are provided on the substrate 100. For example, the first sub-pixel SP1, the second sub-pixel SP2, and the third sub-pixel SP3 can be sequentially arranged in the X-axis direction on the substrate 100. In addition, the first sub-pixel SP1, the second sub-pixel SP2, and the third sub-pixel SP3 can be repeatedly arranged in the Y direction on the substrate 100. The plurality of first sub-pixels SP1 can form a first column in the Y direction, the plurality of second sub-pixels SP2 form a second column in the Y direction, and the plurality of third sub-pixels SP3 can form a third column. For example, the first sub-pixel SP1 can emit light of red, the second sub-pixel SP2 can emit light of green, and the third sub-pixel SP3 can emit light of blue. But embodiments of the present disclosure are not limited thereto, and other colors can be used.

The plurality of emission areas EA1, EA2, and EA3 corresponding to the plurality of sub-pixels SP1, SP2, and SP3 are provided. The first sub-pixel SP1 has the first emission area EA1, the second sub-pixel SP2 has the second emission area EA2, and the third sub-pixel SP3 has the third emission area EA3.

The plurality of emission areas EA1, EA2, and EA3 are defined by the bank 300. Areas exposed without covered by the bank 300 become the plurality of emission areas EA1, EA2, and EA3.

The plurality of anode electrodes 317, 327, and 337 corresponding to the plurality of sub-pixels SP1, SP2, and SP3 are provided. The first anode electrode 317 can be disposed in the first sub-pixel SP1, the second anode electrode 327 can be formed in the second sub-pixel SP2, and the third anode 337 can be disposed in the third sub-pixel SP3. The first to third anode electrodes 317, 327, and 337 can be spaced apart from each other.

The trench TC extending in a Y-axis direction is formed in boundary areas between the plurality of sub-pixels SP1, SP2, and SP3. The trench TC can be formed in the boundary area between the first sub-pixel SP1 and the second sub-pixel SP2, the boundary area between the second sub-pixel SP2 and the third sub-pixel SP3, and the boundary area between the third sub-pixel SP3 and the first sub-pixel SP1.

The trench TC can extend over the plurality of sub-pixels in the Y direction.

The lens structure 600 extending in the Y-axis direction is disposed in the boundary areas between the plurality of sub-pixels SP1, SP2, and SP3. The lens structure 600 can be disposed in the boundary area between the first sub-pixel SP1 and the second sub-pixel SP2, the boundary area between the second sub-pixel SP2 and the third sub-pixel SP3, and the boundary area between the third sub-pixel SP3 and the first sub-pixel SP1.

The lens structure 600 can include a portion that overlaps the trench TC and have a greater width than the trench TC.

The length of the lens structure 600 in the Y direction can be greater than the length of the trench TC. The lens structure 600 can extend over the plurality of sub-pixels in the Y direction.

FIGS. 15 to 17 show a head mounted display device according to one embodiment of the present disclosure.

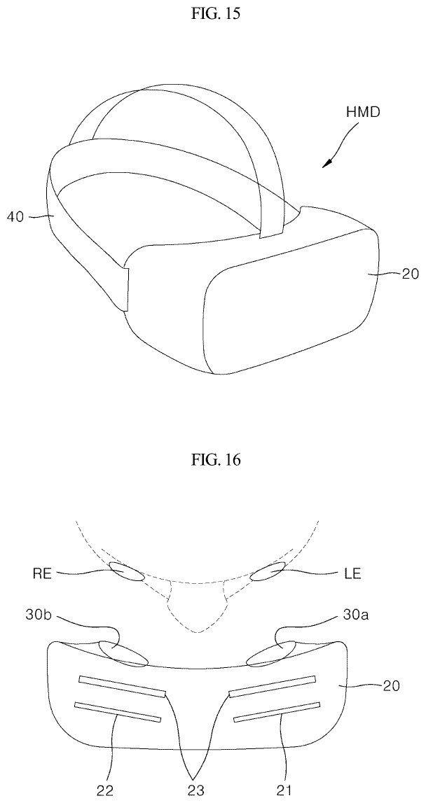

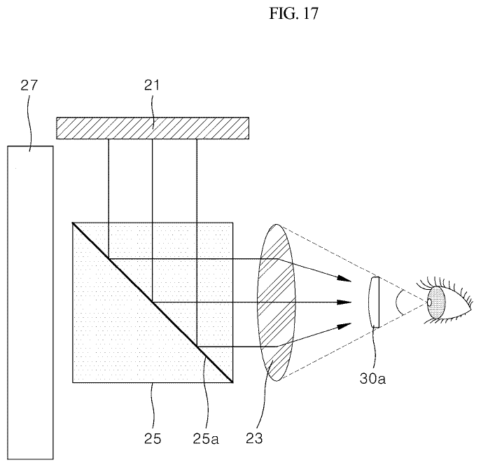

FIG. 15 is a schematic perspective view of a head mounted display device according to one embodiment of the present disclosure, FIG. 16 is a view schematically showing a head mounted display device in which virtual reality (VR) is implemented, and FIG. 17 is a view schematically showing a head mounted display device in which augmented reality (AR) is implemented.

Referring to FIG. 15, the head mounted display device according to one embodiment of the present disclosure includes a storage case 20 and a head mounting band 40.

The storage case 20 stores components, such as a display device, a lens array, and an eyepiece, therein.

The head mounting band 40 is fixed to the storage case 20. An example in which the head mounting band 40 is formed to surround an upper surface and both side surfaces of the user's head, but the present disclosure is not limited thereto. The head mounting band 40 is used to fix the head mounted display to the user's head and can be replaced with a structure in the form of a glasses frame or a helmet.

Referring to FIG. 16, the head mounted display device in which the VR is implemented includes a left-eye display device 21, a right-eye display device 22, a lens array 23, a left-eye eyepiece 30a, and a right-eye eyepiece 30b.

The left-eye display device 21, the right-eye display device 22, the lens array 23, the left-eye eyepiece 30a, and right-eye eyepiece 30b are stored in the storage case 20.

The left-eye display device 21 and the right-eye display device 22 can display the same image, and in this case, the user can view 2D images. Alternatively, the left-eye display device 21 can display left-eye images, and the right-eye display device 22 can display right-eye images, and in this case, the user can view three-dimensional images. The left-eye display device 21 and the right-eye display device 22 can each be provided as one of the above-described organic light emitting diode display device according to FIGS. 1 to 13 and a modified example thereof.

The lens array 23 can be spaced apart from each of the left-eye eyepiece 30a and the left-eye display device 21 and provided between the left-eye eyepiece 30a and the left-eye display device 21. In other words, the lens array 23 can be located in front of the left-eye eyepiece 30a and behind the left-eye display device 21. In addition, the lens array 33 can be spaced apart from each of the right-eye eyepiece 30b and the right-eye display device 22 and provided between the right-eye eyepiece 30b and the right-eye display device 22. In other words, the lens array 23 can be located in front of the right-eye eyepiece 30b and behind the right-eye display device 22.

The lens array 23 can be a micro lens array. The lens array 23 can be replaced with a pin hole array. Due to the lens array 23, images displayed on the left-eye display device 21 and the right-eye display device 22 can be enlarged and visible to the user.

The user's left eye LE can be located behind the left-eye eyepiece 30a, and the user's right eye RE can be located behind the right-eye eyepiece 30b.

Referring to FIG. 17, the head mounted display device in which the AR is implemented includes the left-eye display device 21, the lens array 23, the left-eye eyepiece 30a, a transmission reflector 25, and a transmission window 27. In FIG. 17, only a configuration of the left-eye side is shown for convenience, and a configuration of the right-eye side is also the same or similar to that of the left-eye side.

The left-eye display device 21, the lens array 23, the left-eye eyepiece 30a, the transmission reflector 25, and the transmission window 27 are stored in the storage case 20.

The left-eye display device 21 can be disposed at one side, for example, an upper side of the transmission reflector 25 without blocking the transmission window 27. Therefore, the left-eye display device 21 can provide images to the transmission reflector 25 without covering an external background visible through the transparent window 27.

The left-eye display device 21 can be provided as one of the above-described organic light emitting diode display device according to FIGS. 1 to 13 and a modified example thereof.

The lens array 23 can be provided between the left-eye eyepiece 30a and the transmission reflector 25.

The user's left eye is located behind the left-eye eyepiece 30a.

The transmission reflector 25 is disposed between the lens array 23 and the transmission window 27. The transmission reflector 25 can include a reflective surface 25a for transmitting some of light and reflecting others of the light. The reflective surface 25a includes a semi-transmissive metal film. The semi-transmissive metal film can be made of a semi-transmissive metal material such as magnesium (Mg), silver (Ag), or an alloy of magnesium (Mg) and silver (Ag). The reflective surface 25a is formed so that the images displayed on the left-eye display device 21 proceed to the lens array 23.

Therefore, the user can view both the external background visible through the transmission window 27 and the images displayed by the left-eye display device 21. In other words, since the user can view the real background and the virtual image as one image by allowing the real background and the virtual image to overlap each other, the AR can be implemented.

A display device and a head mounted display device according to embodiments of the present disclosure can be described as follows.

An organic light emitting diode display device according to one embodiment of the present disclosure includes a substrate provided with a first sub-pixel, a second sub-pixel, and a third sub-pixel, a cathode electrode commonly disposed in the first sub-pixel, the second sub-pixel, and the third sub-pixel on the substrate, an encapsulation layer disposed on the cathode electrode, first lens structures disposed in boundary areas between the first to third sub-pixels on the encapsulation layer, and first to third color filters disposed in the first to third sub-pixels, respectively, on the encapsulation layer.

According to one embodiment of the present disclosure, each first lens structure can include a reflective core made of a reflective material, and lenses each disposed on both side surfaces of the reflective core and made of an inorganic material.

According to one embodiment of the present disclosure, one side surface of each lens can be in contact with side surfaces of the reflective core, and the other side surface of each lens can include a convex shape.

According to one embodiment of the present disclosure, an encapsulation layer can include a first inorganic encapsulation layer, an organic encapsulation layer, and a second inorganic encapsulation layer sequentially disposed on the cathode electrode, and the reflective core can extend to the inside of the second inorganic encapsulation layer.

According to one embodiment of the present disclosure, each first lens structure can include a core made of an inorganic material, a reflective layer covering at least both side surfaces of the core and made of a reflective material, and lenses each disposed at both sides of the core and made of an inorganic material in contact with the reflective layer.

According to one embodiment of the present disclosure, the reflective layer can extend to a space between the lenses and the encapsulation layer.

According to one embodiment of the present disclosure, edge portions of the first to third color filters can cover the lenses of the first lens structures, and refractive indexes of the lenses can be smaller than refractive indexes of the first to third color filters.

According to one embodiment of the present disclosure, a planarization layer covering the first lens structures can be further disposed on the encapsulation layer, the first to third color filters can be disposed on the planarization layer, and the refractive indexes of the lenses can be smaller than a refractive index of the planarization layer.

According to one embodiment of the present disclosure, the encapsulation layer can include a first inorganic encapsulation layer, an organic encapsulation layer, and a second inorganic encapsulation layer sequentially disposed on the cathode electrode, and the organic light emitting diode display device can further include second lens structures disposed between the first inorganic encapsulation layer and the organic encapsulation and in the boundary areas between the first to third sub-pixels.

According to one embodiment of the present disclosure, each second lens structure can include a reflective core made of a metal material, and lenses each disposed on both side surfaces of the reflective core and made of an inorganic material.

According to one embodiment of the present disclosure, each second lens structure can include a core made of an inorganic material, a reflective layer covering at least both side surfaces of the core and made of a metal material, and lenses each disposed at both sides of the core and made of an inorganic material in contact with the reflective layer.

According to one embodiment of the present disclosure, refractive indexes of the lenses can be smaller than a refractive index of the organic encapsulation layer.

A head mounted display device according to one embodiment of the present disclosure includes left and right eyepieces, and left-eye and right-eye display devices configured to provide an image to the left and right eyepieces, wherein the left and right eyepieces include a substrate on which a first sub-pixel, a second sub-pixel, and a third sub-pixel are provided, a cathode electrode commonly disposed in the first sub-pixel, the second sub-pixel, and the third sub-pixel on the substrate, an encapsulation layer disposed on the cathode electrode, first lens structures disposed in boundary areas between the first to third sub-pixels on the encapsulation layer, and first to third color filters disposed in the first to third sub-pixels, respectively, on the encapsulation layer.

According to one embodiment of the present disclosure, each first lens structure can include a reflective core made of a reflective material, and lenses each disposed on both side surfaces of the reflective core and made of an inorganic material.

According to one embodiment of the present disclosure, one side surface of each lens can be in contact with side surfaces of the reflective core, and the other side surface of each lens can include a convex shape.

According to one embodiment of the present disclosure, an encapsulation layer can include a first inorganic encapsulation layer, an organic encapsulation layer, and a second inorganic encapsulation layer sequentially disposed on the cathode electrode, and the reflective core can extend to the inside of the second inorganic encapsulation layer.

According to one embodiment of the present disclosure, each first lens structure can include a core made of an inorganic material, a reflective layer covering at least both side surfaces of the core and made of a reflective material, and lenses each disposed at both sides of the core and made of an inorganic material in contact with the reflective layer.

According to one embodiment of the present disclosure, the reflective layer can extend to a space between the lenses and the encapsulation layer.

According to one embodiment of the present disclosure, edge portions of the first to third color filters can cover the lenses of the first lens structures, and refractive indexes of the lenses can be smaller than refractive indexes of the first to third color filters.

According to one embodiment of the present disclosure, a planarization layer covering the first lens structures can be further disposed on the encapsulation layer, the first to third color filters can be disposed on the planarization layer, and the refractive indexes of the lenses can be smaller than a refractive index of the planarization layer.

According to one embodiment of the present disclosure, the encapsulation layer can include a first inorganic encapsulation layer, an organic encapsulation layer, and a second inorganic encapsulation layer sequentially disposed on the cathode electrode, and the organic light emitting diode display device can further include second lens structures disposed between the first inorganic encapsulation layer and the organic encapsulation and in the boundary areas between the first to third sub-pixels.

According to one embodiment of the present disclosure, each second lens structure can include a reflective core made of a metal material, and lenses each disposed on both side surfaces of the reflective core and made of an inorganic material.

According to one embodiment of the present disclosure, each second lens structure can include a core made of an inorganic material, a reflective layer covering at least both side surfaces of the core and made of a metal material, and lenses each disposed at both sides of the core and made of an inorganic material in contact with the reflective layer.

According to one embodiment of the present disclosure, refractive indexes of the lenses can be smaller than a refractive index of the organic encapsulation layer.

According to the embodiments of the present disclosure, since the first distance between the first reflective electrode and the cathode electrode in the first sub-pixel, the second distance between the second reflective electrode and the cathode electrode in the second sub-pixel, and the third distance between the third reflective electrode and the cathode electrode in the third sub-pixel can all be configured differently, it is possible to increase light extraction efficiency of light of different colors, such as red, green, and blue light, in the sub-pixels of the organic light emitting diode display device by the micro cavity effect.

In addition, according to one embodiment of the present disclosure, by arranging the lens structures in the boundary areas between the sub-pixels, the light emitted from one sub-pixel can be blocked from proceeding to another adjacent sub-pixel, and at the same time, the direction of light incident on the lens structure can be changed in the forward direction. Therefore, it is possible to prevent color mixing between the sub-pixels of the organic light emitting diode display device and increase light extraction efficiency.

In addition, it is possible to implement the low-power driving of the organic light emitting diode display device by increasing the light extraction efficiency. In other words, it is possible to reduce the consumed power of the organic light emitting diode display device by increasing the light extraction efficiency.

The effects of the present disclosure are not limited to the above-described effects, and other effects that are not mentioned will be able to be clearly understood by those skilled in the art from the following description.

Although the embodiments of the present disclosure have been described in detail with reference to the accompanying drawings, the present disclosure is not necessarily limited to these embodiments, and various modifications can be carried out without departing from the technical spirit of the present disclosure. Therefore, the embodiments disclosed in the present disclosure are not intended to limit the technical spirit of the present disclosure, but is intended to describe the same, and the scope of the technical spirit of the present disclosure is not limited by these embodiments.

What is claimed is:

1. An organic light emitting diode display device comprising:
a substrate including a first sub-pixel, a second sub-pixel, and a third sub-pixel;
a cathode electrode commonly disposed in the first sub-pixel, the second sub-pixel, and the third sub-pixel on the substrate;
an encapsulation layer disposed on the cathode electrode;
first lens structures disposed in boundary areas between the first to third sub-pixels on the encapsulation layer; and
a first color filter, a second color filter and a third color filter disposed in the first to third sub-pixels, respectively, on the encapsulation layer.

2. The organic light emitting diode display device of claim 1, wherein each first lens structure includes:
a reflective core including a reflective material; and
lenses each disposed on opposite side surfaces of the reflective core and including an inorganic material.

3. The organic light emitting diode display device of claim 2, wherein one side surface of each lens is in contact with side surfaces of the reflective core, and another surface of each lens includes a convex shape.

4. The organic light emitting diode display device of claim 2, wherein the encapsulation layer includes a first inorganic encapsulation layer, an organic encapsulation layer, a second inorganic encapsulation layer sequentially disposed on the cathode electrode, and
wherein the reflective core extends to an inside of the second inorganic encapsulation layer.

5. The organic light emitting diode display device of claim 1, wherein each first lens structure includes:
a core including an inorganic material;
a reflective layer covering at least opposite side surfaces of the core and including a reflective material; and
lenses each disposed at opposite sides of the core and including an inorganic material in contact with the reflective layer.

6. The organic light emitting diode display device of claim 5, wherein the reflective layer extends in a space between the lenses and the encapsulation layer.

7. The organic light emitting diode display device of claim 2, wherein edge portions of the first to third color filters cover lenses of the first lens structures, and
wherein refractive indexes of the lenses are smaller than refractive indexes of the first to third color filters.

8. The organic light emitting diode display device of claim 2, wherein a planarization layer covering the first lens structures is further disposed on the encapsulation layer, and the first to third color filters are disposed on the planarization layer, and
wherein the refractive indexes of the lenses are smaller than a refractive index of the planarization layer.

9. The organic light emitting diode display device of claim 1, wherein the encapsulation layer includes a first inorganic encapsulation layer, an organic encapsulation layer, a second inorganic encapsulation layer sequentially disposed on the cathode electrode, and
wherein the organic light emitting diode display device further includes second lens structures disposed between the first inorganic encapsulation layer and the organic encapsulation layer and in boundary areas between the first to third sub-pixels.

10. The organic light emitting diode display device of claim 9, wherein each second lens structure includes:
a reflective core including a metal material; and
lenses each disposed on opposite side surfaces of the reflective core and including an inorganic material.

11. The organic light emitting diode display device of claim 9, wherein each second lens structure includes:
a core including an inorganic material;
a reflective layer covering at least opposite side surfaces of the core and including a metal material; and
lenses each disposed at opposite sides of the core and including an inorganic material in contact with the reflective layer.

12. The organic light emitting diode display device of claim 10, wherein refractive indexes of the lenses are smaller than a refractive index of the organic encapsulation layer.

13. The organic light emitting diode display device of claim 11, wherein refractive indexes of the lenses are smaller than a refractive index of the organic encapsulation layer.

14. The organic light emitting diode display device of claim 1, wherein at least one of the first lens structures includes a color corresponding to one of the first sub-pixel, the second sub-pixel, and the third sub-pixel.

15. The organic light emitting diode display device of claim 1, wherein a height of at least one of the first lens structures is less than or equal to at least one of the first to third color filters disposed respectively in the first to third sub-pixels.

16. The organic light emitting diode display device of claim 1, wherein the first lens structures have a first end on the encapsulation layer and a second end in the first to third color filters, and wherein the second end is narrow than the first end.

17. The organic light emitting diode display device of claim 1, further comprising trenches in the substrate,
wherein the first lens structures overlap with the trenches, respectively.

18. A head mounting display device comprising:
left-eye and right-eye eyepieces; and
left-eye and right-eye display devices configured to provide images to the left-eye and right-eye eyepieces,
wherein the left-eye and right-eye display devices include the organic light emitting diode display device of claim 1.

19. An organic light emitting diode display device comprising:
a substrate including a plurality of sub-pixels;
a cathode electrode commonly disposed in the plurality of sub-pixels;
an encapsulation layer disposed on the cathode electrode; and
lens structures disposed adjacent to the plurality of sub-pixels to reflect light emitted from the plurality of sub-pixels,
wherein refractive indexes of the lens structures are different from a refractive index of the encapsulation layer.

20. The organic light emitting diode display device of claim 19, further comprising a plurality of color filters disposed in the plurality of sub-pixels, respectively,
wherein the refractive indexes of the lens structures are less than refractive indexes of the plurality of color filters.
